(19) United States
(12) Patent Application Publication
(10) Pub. No.: US 2021/0104786 A1
(43) Pub. Date: Apr. 8, 2021

(54) INDICATION DEVICE AND BATTERY ASSEMBLY

(71) Applicant: SZ DJI TECHNOLOGY CO., LTD., Shenzhen (CN)

(72) Inventors: Dongan WU, Shenzhen (CN); Rongming XIONG, Shenzhen (CN); Yin TANG, Shenzhen (CN); Yun ZHAO, Shenzhen (CN)

(21) Appl. No.: 17/125,127

(22) Filed: Dec. 17, 2020

Related U.S. Application Data
(63) Continuation of application No. PCT/CN2018/092939, filed on Jun. 26, 2018.

(51) Int. Cl. H01M 10/48; F21V 23/04; F21V 8/00

(52) U.S. Cl. CPC H01M 10/488; F21V 23/04; F21Y 2103/33; G02B 6/0068; G02B 6/0045

(57) ABSTRACT

An indication device of a battery includes a compression member and a plurality of light sources. The plurality of light sources are arranged in a ring shape to surround the compression member and configured to indicate power of the battery.

### CROSS-REFERENCE TO RELATED APPLICATION

This application is a continuation of International Application No. PCT/CN2018/092939, filed Jun. 26, 2018, the entire content of which is incorporated herein by reference.

### TECHNICAL FIELD

The present disclosure generally relates to the battery technology field and, more particularly, to an indication device and a battery assembly.

### BACKGROUND

Currently, display of battery power usually uses a row of circular dot indicators or a stripe indicator for indication. A point light is usually used as a light source. When the indicator is lit up, the indicator is easily lit up unevenly, and user experience is poor.

### SUMMARY

Embodiments of the present disclosure provide an indication device of a battery including a compression member and a plurality of light sources. The plurality of light sources are arranged in a ring shape to surround the compression member and configured to indicate power of the battery.

Embodiments of the present disclosure provide a battery assembly including a housing body, a battery, and an indication device. The battery is mounted at the housing body. The indication device is mounted at the housing body and connected to the battery. The device includes a compression member and a plurality of light sources. The plurality of light sources are arranged in a ring shape to surround the compression member and configured to indicate power of the battery.

### BRIEF DESCRIPTION OF THE DRAWINGS

FIG. 1 is a schematic perspective structural diagram of a battery assembly according to some embodiments of the present disclosure.

FIG. 2 is a schematic partial exploded diagram of the battery assembly according to some embodiments of the present disclosure.

FIG. 3 is a schematic partial exploded diagram of the battery assembly from another view angle according to some embodiments of the present disclosure.

FIG. 4 is a schematic perspective diagram of an indication device according to some embodiments of the present disclosure.

FIG. 5 is a schematic plan view of the indication device according to some embodiments of the present disclosure.

FIG. 6 is a schematic cross-sectional view of the indication device along line VI-VI in FIG. 5.

FIG. 7 is a schematic perspective view of a light guide shown in FIG. 2.

FIG. 8 is a schematic perspective view of a light guide shown in FIG. 3.

FIG. 9 is a schematic perspective view of a key shown in FIG. 2.

FIG. 10 is a schematic perspective view of a key shown in FIG. 3.

### REFERENCE NUMERALS

Battery assembly 100, Indication device 10, Housing body 20, Battery 30, First housing 22, Operation hole 222, Second housing 24, Power supply interface 242, Substrate 11, Light source 12, Light guide 13, Light-emitting member 14, Key 15, Switch 16, Fastener 17, First connection member 112, Light guide member 131, Compression member 132, Blocking member 133, First injection slot 134, Second connection member 135, Top surface 1311, Bottom surface 1312, Side surface 1313, Sub top surface 1314, Outer side surface 1315, Inner side surface 1316, Light incidental surface 1317, Reflection surface 1318, Second injection slot 1332, Key hole 142, Light transmission member 144, Third connection member 146, First boss 152, Second boss 154, Step surface 1522, First recessed slot 1524, Rib 1526, Second recessed slot 1542.

### DETAILED DESCRIPTION OF THE EMBODIMENTS

Embodiments of the present disclosure are further described in connection with the accompanying drawings. Same or similar signs in the accompanying drawings represent the same or similar elements or elements having the same or similar functions.

Embodiments described in connection with the accompanying drawings are exemplary and are merely used to explain embodiments of the present disclosure, which cannot be understood as limitations of the present disclosure.

In the present disclosure, unless otherwise specified, a first feature “on” or “under” a second feature may include that the first feature and the second feature may directly contact with each other, or the first feature and the second feature may contact with each other through an intermediate medium. Moreover, the first feature being “above,” “on,” or “over” the second feature on the second feature may include that the first feature may be directly above or obliquely above the second feature, or a horizontal height of the first feature may be higher than a horizontal height of the second feature. The first feature being “below,” “under,” or “underneath” the second feature may include that the first feature may be directly below or obliquely below the second feature, or the horizontal height of the first feature is lower than the horizontal height of the second feature.

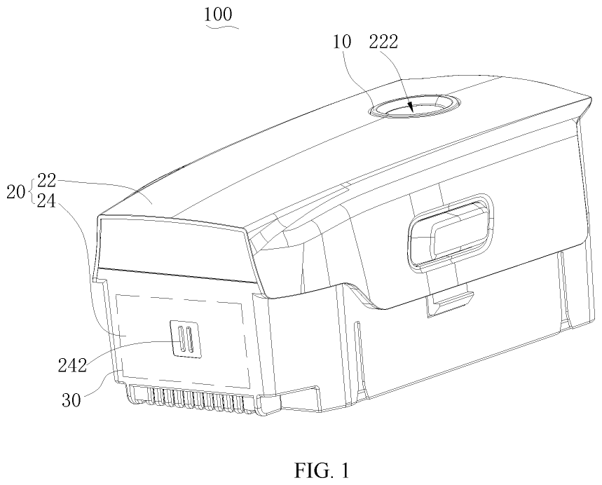

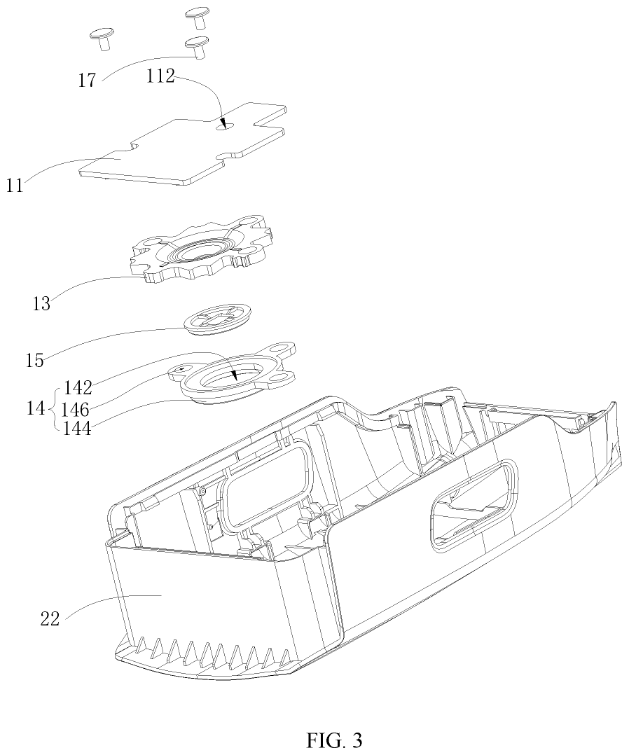

Refer to FIG. 1 to FIG. 3, a battery assembly 100 consistent with embodiments of the present disclosure includes an indication device 10, a housing body 20, and a battery 30. The battery 30 is mounted at the housing body 20. The indication device 10 is mounted at the housing body 20. The indication device 10 may be connected to the battery 30. The battery assembly 100 may be applied in an unmanned machine, a mobile terminal, a head-mount display, etc. The unmanned machine may include an unmanned aerial vehicle (UAV), an unmanned vehicle, an unmanned ship, etc., which is not limited here.

In some embodiments, the housing body 20 includes a first housing 22 and a second housing 24. The first housing 22 and the second housing 24 are combined to form the housing body 20. The first housing 22 and the second housing 24 may be combined through a snap connection, an adhesive connection, or a screw connection. The indication device 10 is mounted at the first housing 22. An operation hole 222 is arranged at the first housing 22. The operation hole 222 is arranged corresponding to the position of the indication device 10. The indication device 10 is arranged at and passes through the operation hole 222 and is exposed by the operation hole 222 to indicate an operation status of the battery 30. The operation status of the battery 30 may include a remaining power status and a power supply status of the battery 30. The battery 30 is mounted at the second housing 24. The second housing 24 is formed with a power supply interface 242. The indication device 10 and the battery 30 may be electrically connected to indicate the operation status of the battery 30.

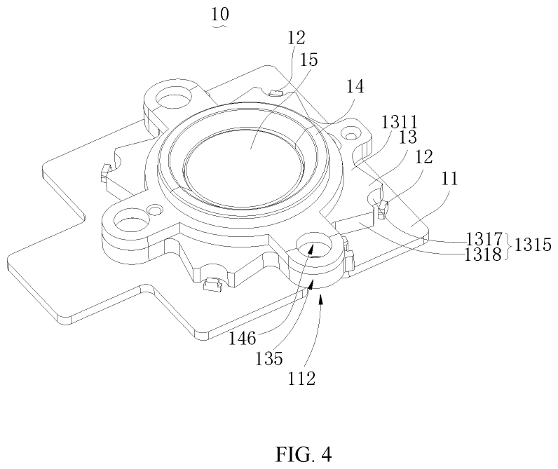

Refer to FIG. 4 to FIG. 6, the indication device 10 of the present disclosure includes a substrate 11, a light source 12, and a light guide 13. The light source 12 is arranged at the substrate 11.

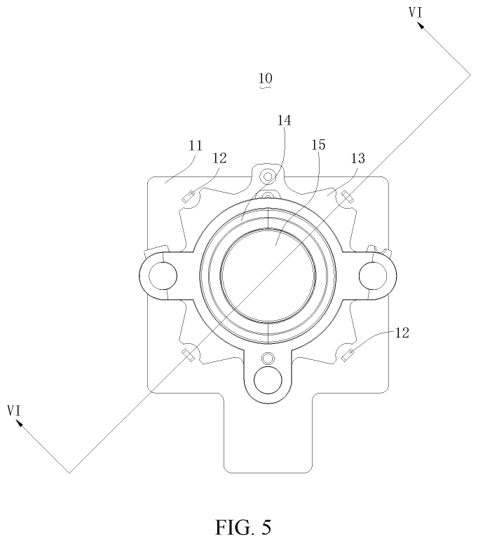

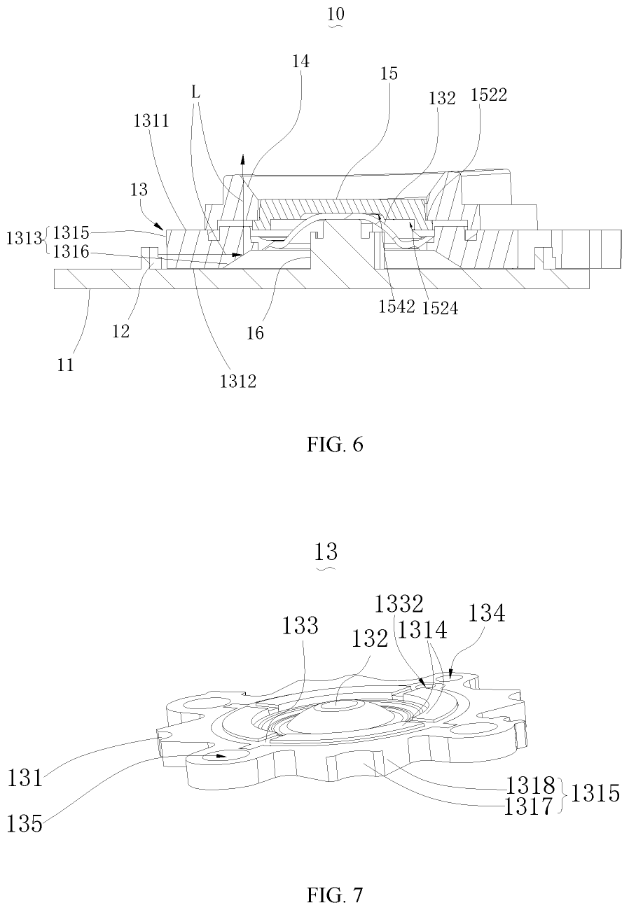

The light guide 13 includes a light guide member 131. The light guide member 131 includes a top surface 1311, a bottom surface 1312, and a side surface 1313. The top surface 1311 faces away from the bottom surface 1312. The side surface 1313 connects the top surface 1311 and the bottom surface 1312. The side surface 1313 includes an outer side surface 1315 and an inner side surface 1316. The bottom surface 1312 is connected with the substrate 11. Refer to FIG. 6, the light source 12 is configured to emit light L toward the outer side surface 1315 to enter the light guide member 131. The light L entering the light guide member 131 may be emitted from the top surface 1311 after being reflected by the inner side surface 1316 to indicate the operation status of the battery 30.

In some embodiments, both the light source 12 and the light guide 13 are arranged at the substrate 11. The light guide 13 and the light source 12 are arranged at an interval. The top surface 1311 faces away from the bottom surface 1312. The side surface connects the top surface 1311 and the bottom surface 1312. The bottom surface 1312 of the light guide 13 is connected with the substrate 11. The outer side surface 1315 is opposite to the inner side surface 1316. A position of the light source 12 is opposite to the outer side surface 1315 and may be configured to emit the light L toward the outer side surface 1315. The light L may pass through the outer side surface 1315, enter the light guide member 131, and be reflected by the inner side surface 1316. The reflected light L may be toward the top surface 1311 and may be emitted from the top surface 1311 to indicate the operation status of the battery 30 (as shown in FIG. 1).

The top surface 1311 of the light guide 131 of the indication device 10 consistent with embodiments of the present disclosure faces away from the bottom surface 1312. After the light L emitted by the light source 12 enters the light guide member 131 from the outer side surface 1315, the light L may be emitted from the top surface 1311 after being reflected by the inner side surface 1316. As such, the light source 12 does not directly illuminate the top surface 1311 to emit light from the top surface 1311, and generation of an excessively bright point to cause an uneven illumination can be prevented. The operation status of the battery 30 may be indicated by the even light L, and the user experience may be great.

A portion of the top surface 1311 of the light guide member 131 located at an upper position of the inner side surface 1316 is parallel to the bottom surface 1312. The inner side surface 1316 is inclined at 45° relative to the bottom surface 1312. Therefore, when the light is ensured to enter the light guide member 131 along a direction parallel to the bottom surface 1312, the light may be reflected by the inner side surface 1316 and emitted from the portion of the top surface 1311 located at the upper position of the inner side surface 1316. Moreover, the light may not be refracted at the portion of the top surface 1311 to reduce light loss.

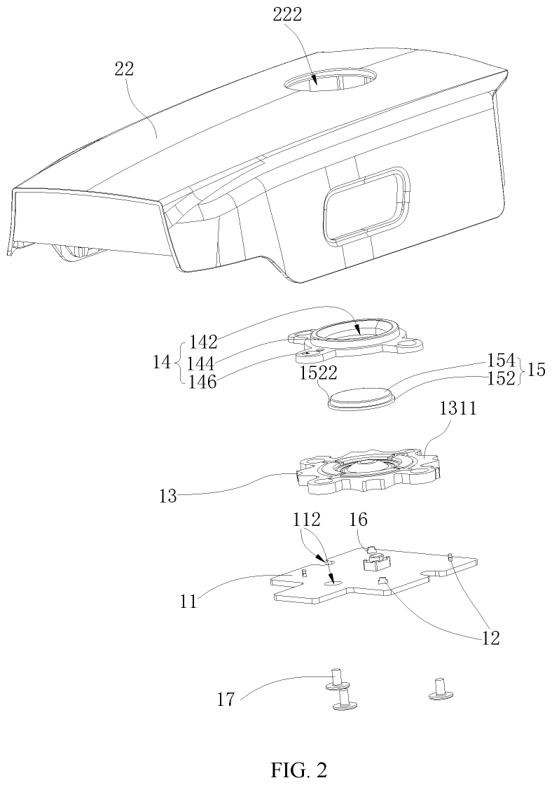

Refer to FIG. 4 to FIG. 6, the indication device includes the substrate 11, the light source 12, the light guide 13, a light-emitting member 14, a key 15, a switch 16, and a fastener 17 (as shown in FIG. 2).

The substrate 11 includes a first connection member 112. The first connection member 112 may be configured to fixedly connect the substrate 11, the light guide 13, and the light-emitting member 14. In some embodiments, the first connection member 112 may be a through hole. The substrate 11 may include a rigid circuit board or a rigid-flex board. As such, the substrate 11 may provide a support function for stabilization. A shape of the substrate 11 may be rectangular, embossed, circular, etc., which is not limited here, as long as the substrate 11 may carry the light source 12, the light guide 13, the light-emitting member 14, the key 15, the switch 16, and the fastener 17.

A plurality of light sources 12 may be included, e.g., two, three, four, etc. The light sources 12 may be arranged at the substrate 11 at intervals around the light guide 13. The light sources 12 may be electrically connected to the substrate 11. The light source 12 may be a light-emitting diode (LED) light. The LED light may be small and easy to realize miniaturization. Moreover, the LED light may be more power-saving and beneficial to save energy. The light source 12 may include another type of light source 12, which is not limited here.

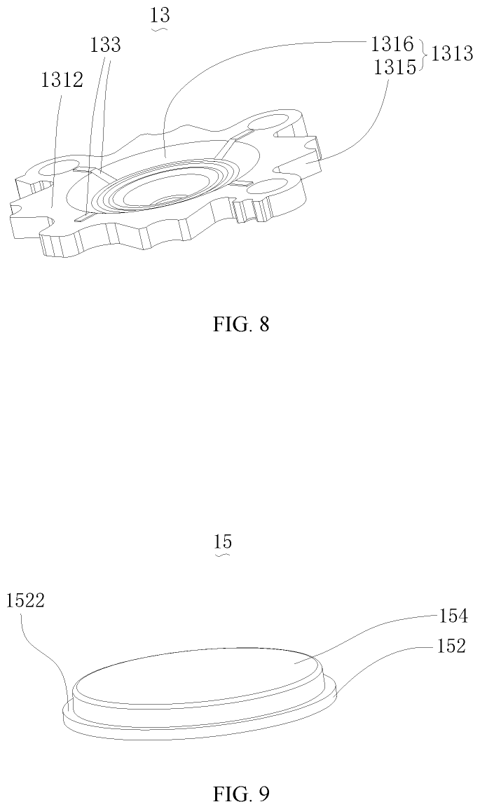

Refer to FIG. 7 and FIG. 8, the light guide 13 includes the light guide member 131, a compression member 132, a blocking member 133, a first injection slot 134, and a second injection slot 135.

The light guide member 131 includes the top surface 1311, the bottom surface 1312, and the side surface 1313. The top surface 1311 faces away from the bottom surface 1312. The side surface 1313 connects the top surface 1311 and the bottom surface 1312. The top surface 1311 includes a plurality of sub top surfaces 1314. The light guide member 131 has a ring shape. In this disclosure, “ring shape” refers to a shape that partially or completely encloses an area or a space and may include, e.g., a circular ring shape or a rectangular ring shape. In some embodiments, the light guide member 131 may have a circular ring shape. The light guide member 131 may be connected with the substrate 11 through the bottom surface 1312.

The side surface 1313 includes the outer side surface 1315 and the inner side surface 1316 facing away from the outer side surface 1315. An area covered by connection lines of the light source 12 and an edge of a curved surface may cover an illuminating area of the light source 12. That is, the illuminating area of the light source 12 may be covered by the curved surface. All light emitted by the light source 12 may illuminate at the curved surface. Thus, the light emitted by the light source 12 may be maximumly used. In some other embodiments, a light incidental surface 1317 may include other shapes, such as a planar surface, etc., as long as the light incidental surface 1317 may cover the illuminating area of the light.

A reflection surface 1318 extends along both sides of the curved surface. A reflection film may be arranged over the reflection surface 1318, the reflection surface 1318 may be performed with a polishing process, or the reflection surface 1318 may be performed with the polishing process and be arranged with the reflection film. As such, the reflection surface 1318 may sufficiently reflect the incidental light from the light source 12 to prevent the light to be emitted from the reflection surface 1318, thus, the light of the light source 12 may be sufficiently used. After being reflected by the reflection surface 1318, the light may be emitted toward the inner side surface 1316. The inner side surface 1316 may be similar to the reflection surface 1318. The inner side surface 1316 may be arranged with the reflection film or performed with the polishing process, or may be arranged with the reflection film and performed with the polishing process. The inclined angle of the inner side surface 1316 may be an acute angle to an incidental direction of the light. By changing the incidental direction of the light, the light may be reflected toward the top surface 1311 to be emitted from the top surface 1311. Thereby, the operation status of the battery 30 may be indicated.

The compression member 132 is connected to the blocking member 133, and the compression member 132 and the blocking member 133 may be made of a same material. The compression member 132 is arranged at the center of the ring shape of the light guide member 131. The compression member 132 may be a round arch. The compression member 132 and the blocking member 133 may be formed integrally by using the same material. The compression member 132 may be an elastic element. For example, the compression member 132 may include a rubber material or a soft rubber material. Both rubber and soft rubber may have a certain elasticity. Since the compression member 132 is the round arch, after being compressed, the compression member 132 may return to a status before being compressed autonomously.

A second injection slot 1332 is arranged at the blocking member 133. The blocking member 133 passes through the light guide member 131 and divides the top surface 1311 of the light guide member 131 into a plurality of sub top surfaces 1314, for example, two, three, or four. The number of the sub top surfaces 1314 may be designed according to accuracy of power indication. The blocking member 133 may include an opaque material, such as rubber, and may divide adjacent sub top surfaces 1314. The light may not be transmitted between portions of the light guide member 131 corresponding to the adjacent sub top surfaces 1314. That is, the portion of the light guide member 131 corresponding to each sub top surface 1314 may be divided by the blocking member 133, such that each sub top surface 1314 may form an individual illuminating area. Correspondingly, an area of the indication device 10 corresponding to the sub top surface 1314 may be lit up to visually indicate the operation status of the battery 30.

Each sub top surface 1314 may correspond to at least one light source 12. That is, the light emitted from each sub top surface 1314 may be from at least one light source 12 to ensure the brightness of the illumination. The light guide 131 may include a different material from the compression member 132, but the compression member 132 and the blocking member 133 may include a same material. Hence, the light guide member 131 and the compression member 132 may include different materials, and the light guide member 131 and the blocking member 133 may include different materials too. Such the light guide member 13 may be formed integrally by a dual-color injection molding process. The light guide 131 may be formed by injecting the material (e.g., melted plastic) into the first injection slot 134. The blocking member 133 and the compression member 132 may be formed by injecting the material (e.g., melted rubber) into the second injection slot 1332. These processes are mature, and automatic production may be easy to realize. A position of a second connection member 135 corresponds to a position of the first connection member 112. The second connection member 135 may be a through hole. As shown in FIG. 7, the through hole is arranged at a first lug. The first lug may extend from the edge of the light guide member 131.

The light-emitting member 14 includes a key hole 142, a light transmission member 144, and a third connection member 146. The light-emitting member 14 is arranged at the top surface 1311. The light may illuminate the light-emitting member 14 after being emitted from the top surface 1311. The light transmission member 144 is arranged around the key hole 142. The light transmission member 144 may be a ring shape. The light transmission member 144 may include a light transmission material, for example, glass, plastic, etc., having a high transmittance. A plurality of virtual light transmission areas (the light transmission member 144 is not actually divided into a plurality of divided areas, to facilitate the description of the areas of the light transmission member 144 corresponding to the sub top surfaces 1314, the light transmission member 144 is divided into the plurality of virtual light transmission areas) corresponding to the number of the sub top surfaces 1314 may be formed at the light transmission member 144. Because different sub top surfaces 1314 are divided by the opaque blocking member 133, the light transmission area may be formed with a dark portion corresponding to the blocking member 133 and a bright portion corresponding to the sub top surface 1314. When a power operation status is indicated, the corresponding light source 12 may emit the light to cause the light to be emitted from the corresponding sub top surface 1314 to illuminate the corresponding light transmission area of the light-emitting member 14 to light up according to the power of the battery 30. As such, the power may be indicated clearly and visually. A position of the third connection member 146 corresponds to the position of the second connection member 135. The third connection member 146 may be a through hole. As shown in FIG. 4, the through hole is arranged at a second lug. The second lug may extend from the edge of the light transmission member 144. The fastener 17 may fixedly mount the substrate 11, the light guide 13, and the light-emitting member 14 at the inner wall of the first housing 22 through the first connection member 112, the second connection member 135, and the third connection member 146. The fastener 17 may be a screw or other appropriate parts, as long as the fastener 17 can cooperate with the first connection member 112, the second connection member 135, and the third connection member 146 to fixedly mount the substrate 11, the light guide 13, and the light-emitting member 14 at the inner wall of the first housing 22.

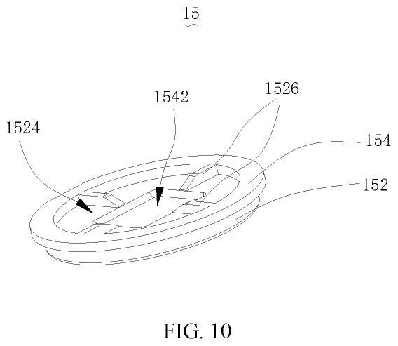

Refer to FIG. 9 and FIG. 10, the key 15 includes a first boss 142 and a second boss 154. The key 15 is arranged at a side of the compression member 132 away from the substrate 11. The second boss 154 may be formed by extending from a top surface of the first boss 152. The top surface of the first boss 152 may be formed with a step surface 1522 around the second boss 154. A bottom surface of the first boss 152 may be recessed toward the second boss 154 to form a first recessed slot 1524. A bottom surface of the second boss 154 may be recessed toward a top surface of the second boss 154 to form a second recessed slot 1542. The first recessed slot 1524 may be around the second recessed slot 1544. A plurality of ribs 1526 may be formed in the first recessed slot 1524 and extend from an edge of the first recessed slot 1524 to the second recessed slot 1542. The plurality of ribs 1526 are arranged around the second recessed slot 1542. A number of the ribs 1526 may be at least two, for example, two, three, four, five, etc. In some embodiments, the number of the ribs 1526 is four. The four ribs 1526 may cooperate to be stably loaded at the compression member 132. The shape of the ribs 1526 may cooperate with the shape of the compression member 132. The second recessed slot 1542 and the plurality of ribs 1526 may cooperate with the shape of the compression member 132 to cause the key 15 to be loaded at the compression member 132. After the key 15 is pressed, the compression member 132 may be evenly pressed to generate an elastic deformation. The light-emitting member 14 may be loaded at the key 15. The bottom surface of the light transmission member 144 abuts the step surface 1522. The key 15 is exposed by the key hole 142 of the light-emitting member 14. After the key 15 is pressed, the compression member 132 may be evenly pressed to cause the compression member 132 to deform. After the light-emitting member 14 and the light guide 13 are fixed together by the fastener 17, the bottom surface of the light transmission member 144 abutting the step surface 1522 may further prevent the key 15 from falling off from the key hole 142.

The switch 16 is arranged at the substrate 11 corresponding to the position of the compression member 132. The portion of the compression member 132 located at the second recessed slot 1542 is loaded at the switch 16. The switch 16 may be an elastic part. After being pressed to generate a deformation, the switch 16 may restore the deformation, which is convenient for a user to press the switch 16 multiple times. The compression member 132 blocks the key 15 and the switch 16. The compression member 132 may be an elastic part too, and the material of the compression member 132 may be softer. Thus, the compression member 16 may protect the switch 16. After the key 15 is pressed, the compression member 132 may be caused to generate the elastic deformation to trigger the switch 16.

The battery assembly 100 may control at least one of the indication device 10 or the battery 30 to execute a corresponding operation according to different trigger actions. For example, the battery assembly 100 may control a predetermined number of light sources 12 of the indication device 10 to light up to cause the light to pass through the corresponding sub top surfaces 1314 to illuminate the light transmission area. Thus, the corresponding light transmission area may be lit up to indicate the power operation status of the battery 30. The predetermined number may be positively correlated to the power of the battery 30. For example, if a first trigger action is short pressing, the number of the light sources 12 is four, the four light sources 12 are evenly distributed around the center (e.g., the center of the switch 16) of the compression member 132, and each sub top surface 1314 corresponds to one light source 12, at this point, four light transmission areas may exist, and each light source 12 may correspond to one light transmission area. After the user short-presses the key 15, only one light source 12 may emit the light when the power of the battery 30 is from 0% to 25%, that is, one light transmission area may be lit up. Two light sources 12 may emit the light when the power of the battery is from 25% to 50%, that is, two light transmission areas may be lit up. Three light sources 12 may emit the light when the power of the battery 30 is from 50% to 75%, that is, three light transmission areas may be lit up. Four light sources 12 may emit the light when the power of the battery 30 is from 75% to 100%, that is, four light transmission areas may be lit up. As such, the power may be indicated visually. More light sources 12 may further be arranged corresponding to the light transmission areas (e.g., 10 light sources 12 may be arranged, and each light source 12 corresponds to one light transmission area) to indicate the power more accurately. The number of the light sources 12 may be designed according to the requirements of the indication accuracy and power-saving.

For another example, the plurality of light sources 12 may emit the light alternately according to a second trigger action to cause the corresponding light transmission areas to be lit up. For example, the second trigger action is double-pressing, the light sources 12 is four, and each sub top surface 1314 corresponds to one light source 12. After the user double-presses the key 15, the light sources 12 may be turned on in sequence clockwise, and a previous light source 12 may be turned off when a next light source 12 is turned on, similar as a marquee light effect.

For another example, the battery 30 may supply power to external equipment through a power supply interface 242 according to a third trigger action. For example, the third trigger action may be short-pressing at first and then long-pressing. After the user short-presses the key 15 first and then long-presses the key 15, the battery 30 may be controlled to supply power to the external equipment connected to the power supply interface 242 through the power supply interface 242.

The first trigger action, the second trigger action, and the third trigger action may be triggered individually or simultaneously. For example, the first trigger action and the second trigger action may be the same, for example, the short-pressing. After the user short-presses the key 15, the operation corresponding to the second trigger action may be performed first, the operation corresponding to the first trigger action may be performed subsequently. That is, after the key 15 is short-pressed, the marquee light effect may be realized first. The corresponding light sources 12 may be controlled to emit light to indicate the power state according to the power state of the battery 30. Thereby, the power may be indicated in a cool style. Embodiments of the present disclosure are not limited to the first trigger action, the second trigger action, and the third trigger action. A fourth trigger action may be included, for example, long-pressing, which is used to control the battery 30 to stop supplying power to the external equipment. The indication device 10 may maintain to be in a sleep mode without receiving any trigger actions, that is, the light source 12 may be maintained not to emit light. As such, the power may be saved. In some other embodiments, the indication device 10 may be lit up all the time to indicate the power state of the battery 30. The user does not need to actively control the indication device 10 to indicate the power state through a trigger action, and the user experience is great.

In summary, the top surface 1311 and the bottom surface 1312 of the light guide member 131 of the indication device 10 consistent with embodiments of the present disclosure face away from each other. The plurality of light sources 12 are included, and the light sources 12 are aligned with the light incidental surfaces 1317. The light source 12 may be configured to emit light toward the light incidental surface 1317. After entering the light guide member 131 from the light incidental surface 1317, the light may be reflected by the light reflection surface 1318 and the inner side surface 1316 and emitted from the sub top surface 1314 corresponding to the light source 12. The different sub top surfaces 1314 may be divided by the opaque blocking member 133. The light emitted from the different sub top surfaces 1314 may illuminate the corresponding light transmission areas to light up the light transmission areas. The adjacent light transmission areas may be divided by the dark portion corresponding to the blocking member 133. The predetermined number of the light sources 12 may be controlled to emit light to light up the corresponding light transmission areas according to the battery 30 operation status to indicate the battery 30 operation status. The light source 12 may be prevented from directly illuminating the sub top surface 1314 to cause excessively bright point at the corresponding light transmission area to cause the uneven distribution of brightness, and the user experience may be affected.

In some embodiments, the light source 12 may be one. The light source 12 may emit light of different colors. The light source 12 corresponds to the whole top surface 1311 (i.e., the light emitted from the one light source 12 may be emitted from the whole top surface 1311). When the light source 12 emits the light, the light may be emitted from the top surface 1311 to light up the whole light transmission member 144. The light source 12 may use different colors corresponding to different percentages of the power to indicate the power.

In some embodiments, the one light source 12 may emit light of different colors. For example, the light source 12 may emit light of four colors (e.g., green, blue, yellow, and red). Green light may indicate that the power of the battery 30 may be from 75% to 100%. Blue light may indicate that the power of the battery 30 may be from 50% to 75%. Yellow light may indicate that the power of the battery 30 may be from 25% to 50%. Red light may indicate that the power of the battery 30 may be from 0% to 25%. As such, the light transmission member 144 may be ensured to emit light evenly, and only one light source 12 may be included, which is more power-saving. In addition, by using different colors to indicate the power, it is simple and direct, and the user experience is great.

In the description of this specification, the description of reference terms of “certain embodiments,” “one embodiment,” “some embodiments,” “examples,” “specific examples,” or “some examples,” etc., means that specific features, structures, materials, or characteristics described in connection with embodiments or examples are included in at least one embodiment or example of the present disclosure. In this specification, schematic representation of the above-mentioned terms does not necessarily refer to same embodiments or examples. Moreover, the described specific features, structures, materials, or characteristics can be combined in any one or more embodiments or examples in a suitable manner. In addition, when there is no conflict, those skilled in the art can combine and group different embodiments or examples and the characteristics of different embodiments or examples described in this specification.

In addition, the terms “first” and “second” are only used for descriptive purposes, and cannot be understood as indicating or implying relative importance or implicitly indicating the number of indicated technical features. Therefore, the features defined with “first” and “second” may explicitly or implicitly include at least one of the features. In the description of the present disclosure. “Plurality of” means at least two, such as two or three, unless otherwise specifically defined.

Although embodiments of the present disclosure have been shown and described above, the above-mentioned embodiments are exemplary and should not be understood as a limitation of the present disclosure. Those of ordinary skill in the art may modify, change, replace, and variate embodiments of the present disclosure within the scope of the present disclosure. The scope of the present invention is defined by the claims and their equivalents.

What is claimed is:

1. An indication device of a battery comprising:
a compression member; and
a plurality of light sources arranged in a ring shape to surround the compression member and configured to indicate power of the battery.

2. The device of claim 1, wherein the ring shape includes a circular ring shape or a rectangular ring shape.

3. The device of claim 1, wherein the compression member is configured to act in response to one or more of a plurality of trigger actions to control the plurality of light sources to emit light in one or more corresponding manners.

4. The device of claim 3, wherein the plurality of trigger actions include:
a first trigger action that triggers the compression member to control a predetermined number of the plurality of light sources to emit light to indicate the power of the battery;
a second trigger action that triggers the compression member to control the plurality of light sources to emit light alternately to light up corresponding light transmission areas; and
a third trigger action that triggers the compression member to control the battery to supply power to an external device via a power supply interface.

5. The device of claim 4, wherein the predetermined number is positively correlated to the power of the battery.

6. The device of claim 3, wherein the plurality of trigger actions individually or synchronously trigger the compression member.

7. The device of claim 3, wherein the compression member is further configured to be triggered to control the battery to stop supplying power to the external device.

8. The device of claim 1, wherein:
the plurality of light sources are configured to remain off in a sleep mode without receiving any trigger action; or
the plurality of light sources are configured to remain on to indicate the power of the battery.

9. The device of claim 1, wherein at least one of the plurality of light sources is configured to emit light of different colors used to indicate the power of the battery.

10. The device of claim 9, wherein the different colors correspond to different levels of the power of the battery.

11. The device of claim 1, further comprising:
a substrate including the plurality of light sources; and
a light guide configured to guide and emit light from the plurality of light sources to indicate an operation status of the battery.

12. The device of claim 11, wherein the light guide includes a light guide member, wherein:
the light guide member includes a top surface, a bottom surface, and a side surface;
the top surface faces away from the bottom surface;
the side surface is configured to connect the top surface and the bottom surface;
the side surface includes an outer side surface and an inner side surface;
the bottom surface is connected with the substrate;
one of the plurality of light sources is configured to emit light toward the outer side surface to enter the light guide member; and
the light having entered the light guide member is emitted from the top surface after being reflected by the inner side surface to indicate the operation status of the battery.

13. The device of claim 12, wherein:
the outer side surface includes a light incidental surface;
the light source is aligned with the light incidental surface; and
the light emitted by the one of the plurality of light sources passes through the light incidental surface to enter the light guide member.

14. The device of claim 13, wherein:
the light incidental surface includes a curved surface; and
an area covered by connection lines of the light source and an edge of the light incidental surface covers an illumination area of the one of the plurality of light sources.

15. The device of claim 12, wherein the outer side surface includes a reflection surface configured to reflect the light entered the light guide member to prevent the light from being emitted from the reflection surface.

16. The device of claim 12, wherein:
the light guide member as a whole has a ring shape; and
the compression member is arranged at a center of the light guide member.

17. The device of claim 16, wherein the light guide further includes an opaque blocking member configured to divide the top surface of the light guide member into a plurality of sub top surfaces.

18. The device of claim 17, wherein:
the plurality of light sources are arranged around the light guide member at intervals; and
each of the sub top surfaces corresponds to a position of the one of the plurality of light sources.

19. The device of claim 16, further comprising:
a switch configured to be triggered to control the light source to emit light, the switch being arranged at the substrate and corresponding to a position of the compression member;
wherein the compression member is configured to be pressed to generate an elastic deformation to trigger the switch.

20. A battery assembly comprising:
a housing body;
a battery mounted at the housing body; and
an indication device mounted at the housing body and connected to the battery, and including:
a compression member; and
a plurality of light sources arranged in a ring shape to surround the compression member and configured to indicate power of the battery.
